(19) United States
(12) Patent Application Publication
(10) Pub. No.: US 2016/0028983 A1
(43) Pub. Date: Jan. 28, 2016

(54) SOLID-STATE IMAGE PICKUP DEVICE AND CAMERA MODULE

(71) Applicant: Kabushiki Kaisha Toshiba, Minato-ku (JP)

(72) Inventors: Shinji UYA, Oita (JP); Yusuke Kohyama, Oita (JP)

(73) Assignee: Kabushiki Kaisha Toshiba, Minato-ku (JP)

(21) Appl. No.: 14/791,580

(22) Filed: Jul. 6, 2015

(30) Foreign Application Priority Data
Jul. 24, 2014 (JP) 2014-151182

(51) Int. Cl. H04N 5/374; H01L 27/146; H04N 5/369; H04N 5/232; H04N 5/225

(52) U.S. Cl. CPC H04N 5/3742; H04N 5/23212; H04N 5/2254; H04N 5/369; H01L 27/14627

(57) ABSTRACT

According to an embodiment, a solid-state image pickup device is provided. The solid-state image pickup device includes a sensor substrate, microlenses, and a flattened layer. The sensor substrate is provided with a plurality of photoelectric conversion elements arranged in a two-dimensional array shape. The microlenses are provided at positions facing light receiving surfaces of the plurality of photoelectric conversion elements, respectively, and collect incident light onto the photoelectric conversion elements. The flattened layer is provided on a light incident side of the microlenses and has a refractive index which is higher than a refractive index of air and is 1/1.3 times or less of a refractive index of the microlenses.

### CROSS-REFERENCE TO RELATED APPLICATIONS

This application is based upon and claims the benefit of priority from Japanese Patent Application No. 2014-151182, filed on Jul. 24, 2014; the entire contents of which are incorporated herein by reference.

### FIELD

The present embodiment generally relates to a solid-state image pickup device and a camera module.

### BACKGROUND

Recently, a solid-state image pickup device applied to a camera module achieves high resolution in such a manner of reducing a size of pixel and increasing the number of pixels per unit area.

In an optical system including an image pickup lens to be used in the camera module, however, there is a limit to resolving power of the lens due to a diffraction limit or an aberration of the image pickup lens. Therefore, in the existing solid-state image pickup device, when the size of pixel is reduced up to a predetermined level, the resolution is not improved even if the size of pixel becomes further smaller.

### BRIEF DESCRIPTION OF THE DRAWINGS

FIG. 1 is a cross-sectional view illustrating a schematic configuration of a camera module according to a first embodiment;

FIG. 2 is an explanatory diagram schematically illustrating the camera module according to the first embodiment;

FIGS. 3A and 3B are schematic cross-sectional views illustrating a process of fabricating a solid-state image pickup device according to the first embodiment, respectively;

FIGS. 4A and 4B are schematic cross-sectional views illustrating a process of fabricating the solid-state image pickup device according to the first embodiment, respectively; and

FIG. 5 is an explanatory diagram schematically illustrating a camera module according to a second embodiment.

### DETAILED DESCRIPTION

In general, according to one embodiment, a solid-state image pickup device is provided. The solid-state image pickup device includes a sensor substrate, microlenses, and a flattened layer. The sensor substrate is provided with a plurality of photoelectric conversion elements arranged in a two-dimensional array shape. The microlenses are respectively provided at positions facing light receiving surfaces of the plurality of photoelectric conversion elements, and collect incident light onto the photoelectric conversion elements. The flattened layer is provided on a light incident side of the microlenses and has a refractive index which is higher than a refractive index of air and is 1/1.3 times or less of a refractive index of the microlenses.

Exemplary embodiments of a solid-state image pickup device and a camera module will be described below in detail with reference to the accompanying drawings. The present invention is not limited to the following embodiments.

### First Embodiment

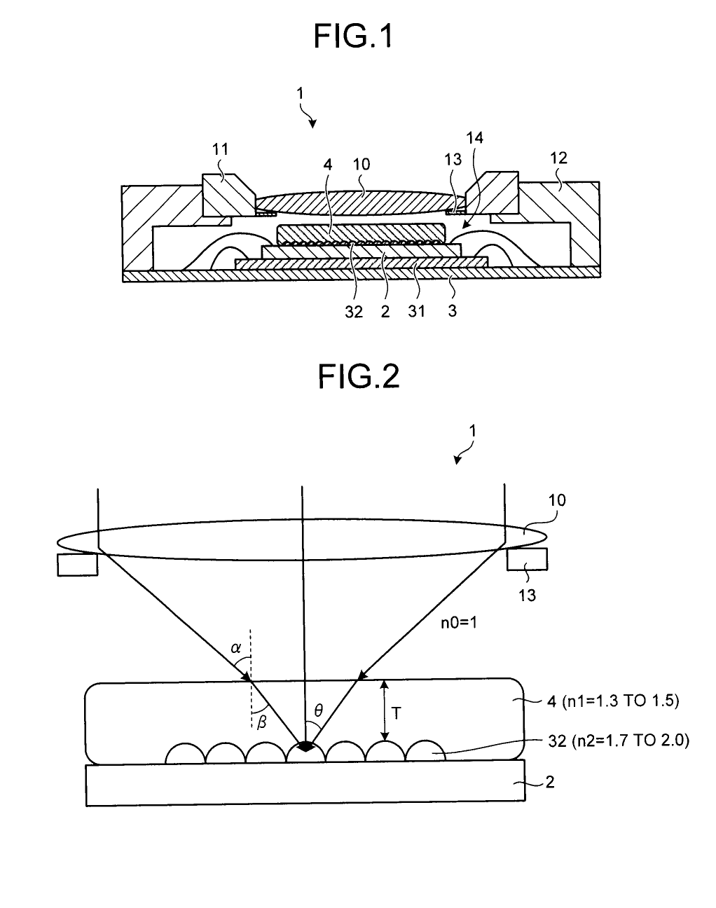

FIG. 1 is a cross-sectional view illustrating a schematic configuration of a camera module 1 according to a first embodiment, and FIG. 2 is an explanatory diagram schematically illustrating the camera module 1 according to the first embodiment. As illustrated in FIG. 1, the camera module 1 includes an image pickup lens 10, a lens holder 11, a shield case 12, a ceramic substrate 3, and a solid-state image pickup device 14.

The shield case 12 is a box-shaped case in which a bottom thereof is opened and a circular opening is provided on a center of a top. The lens holder 11 is an annular member engaged with the opening provided on the top of the shield case 12 and supports a peripheral portion of the image pickup lens 10.

The image pickup lens 10 captures light from an object and forms an object image on the solid-state image pickup device 14. A diaphragm unit 13 is provided at an inner peripheral edge portion of the lens holder 11 and can adjust the amount of light incident from the image pickup lens 10.

The ceramic substrate 3 is a cover configured to close the opened bottom of the shield case 12. The solid-state image pickup device 14 is provided in an internal space which is surrounded by the ceramic substrate 3, the shield case 12, and the image pickup lens 10. Specifically, the solid-state image pickup device 14 is provided at the center on the ceramic substrate 3 such that an optical axis of the light incident from the image pickup lens 10 is the center of a light receiving surface.

The solid-state image pickup device 14 includes a logic substrate 31 provided on the ceramic substrate 3, a sensor substrate 2 provided on the logic substrate 31, a plurality of microlenses 32 provided on the top of the sensor substrate 2, the top serving as a light receiving surface, and a flattened layer 4 configured to cover the microlenses 32.

The sensor substrate 2 includes an image sensor which picks up the image of the object. The image sensor is a CMOS (Complementary Metal Oxide Semiconductor) image sensor. The image sensor may be another image sensor such as a CCD (Charge Coupled Device) sensor.

The CMOS image sensor includes a plurality of photoelectric conversion elements which are arranged in a two-dimensional array shape. Each of the photoelectric conversion elements corresponds to each pixel of the picked-up image and converts the incident light into a signal charge, thereby accumulating the signal charge. The microlens 32 is a plano-convex lens having a semispherical light receiving surface and collects the incident light on the photoelectric conversion element.

The logic substrate 31 includes a logic circuit such as a DSP (Digital Signal Processor) that reads out the signal charge from the photoelectric conversion element in the sensor substrate 2 and performs various signal processing operations on the read-out signal charge.

The flattened layer 4 is provided to cover and seal the microlens 32. The flattened layer 4 is formed of a material having a higher refractive index than air and a lower refractive index than the microlens 32.

Furthermore, in this embodiment, a ratio of a refractive index n1 of the flattened layer 4 to a refractive index n2 of the microlens 32 is optimized, and thus resolving power of the image pickup lens 10 is improved without deterioration of light-collecting characteristics of the microlens 32 and resolution of the camera module 1 is improved.

Here, operation effects will be described which are caused in the cases where the flattened layer 4 is provided and the ratio of the refractive index n1 of the flattened layer 4 to the refractive index n2 of the microlens 32 is optimized. First, the resolving power of the image pickup lens 10 will be described.

In order to clarify the effects caused in the cases where the flattened layer 4 is provided and the ratio of the refractive index n1 of the flattened layer 4 to the refractive index n2 of the microlens 32 is optimized, a case where the flattened layer 4 is not provided will be daringly described herein as an example.

When the flattened layer 4 is not provided in the camera module 1, air (n0=1) is interposed between the microlens 32 and the image pickup lens 10. In this case, resolving power ω of the image pickup lens 10 can be expressed by the relational expression represented in Formula (1) to be described below using a numerical aperture NA of the image pickup lens 10 and a wavelength λ of light incident on the image pickup lens 10.

ω=(0.61×λ)/NA (1)

In addition, the numerical aperture NA can be expressed by the relational expression represented in Formula (2) to be described below using a maximum angle θ with respect to the optical axis of a light beam incident on the microlens 32 from the image pickup lens 10 and the refractive index n0 of the air.

NA=n0·sin θ (2)

The resolving power ω of the image pickup lens 10 can be expressed by the relational expression represented in Formula (3) to be described below using Formulas (1) and (2) described above.

ω=(0.61×λ)/(n0·sin θ) (3)

As represented in Formula (3) described above, the resolving power ω of the image pickup lens 10 becomes higher as the refractive index (here, corresponding to the refractive index n0 of the air) of a medium interposed between the image pickup lens 10 and the microlens 32 becomes larger.

Therefore, as illustrated in FIG. 2, the flattened layer 4 having the larger refractive index than the air is provide between the microlens 32 and the image pickup lens 10 in the camera module 1. Thus, the image pickup lens 10 of the camera module 1 can be improved in resolving power ω compared with a case where the flattened layer 4 is not provided between the microlens 32 and the image pickup lens 10.

However, when only the flattened layer 4 having the larger refractive index than the air is provided between the microlens 32 and the image pickup lens 10, there is a case where the light-collecting characteristics of the microlens 32 deteriorate. For example, when the refractive index n1 of the flattened layer 4 is approximately similar to the refractive index n2 of the microlens 32, a refractive angle becomes large at the interface between the flattened layer 4 and the microlens 32 and light incident on the microlens 32 hardly reaches the light receiving surface of the photoelectric conversion element.

In the camera module 1, therefore, when the ratio of the refractive index n1 of the flattened layer 4 to the refractive index n2 of the microlens 32 is optimized, the deterioration of the light-collecting characteristics of the microlens 32 is prevented.

Specifically, the microlens 32 can sufficiently ensure the light-collecting characteristics when the refractive index n2 thereof is 1.3 times or more of the refractive index n1 of the flattened layer 4. In other words, the microlens 32 can sufficiently exhibit the light-collecting characteristics when the refractive index n1 of the flattened layer 4 is 1/1.3 times or less of the refractive index n2 of the microlens 32.

The resolution on the microlens 32 becomes higher as the refractive index n1 of the flattened layer 4 becomes higher. Meanwhile, light-collecting power of the microlens 32 becomes stronger in response to the difference between the refractive index n2 of the microlens 32 and the refractive index n1 of the flattened layer 4. The present inventors repeatedly perform optical simulation by changing the value of the refractive index n1 and the value of the refractive index n2 and consequently confirm that the refractive index n1 is 1/1.3 times or less than the refractive index n2 as a minimally necessary condition.

In the camera module 1, accordingly, the refractive index n1 of the flattened layer 4 is set to be 1/1.3 times or less than the refractive index n2 of the microlens 32. Thus, the resolving power Co of the image pickup lens 10 is improved without the deterioration of the light-collecting characteristics of the microlens 32, so that the resolution of the camera module 1 can be improved.

Here, the flattened layer 4 is formed of, for example, SiO2 (silicon oxide) material called a porous silica or a hollow silica containing bubbles therein, and thus the refractive index n1 thereof becomes 1.3 to 1.5 higher than that of the air. In this case, the refractive index of 1.3 times or more of the refractive index n1 of the flattened layer 4 is required for the microlens 32.

However, it is difficult to achieve the refractive index of 1.3 times or more of 1.3 to 1.5 in an organic resin which is generally used as a material of the microlens 32. Therefore, the camera module 1 is provided with the microlens 32 formed of TiO₂ (titanium oxide) material having the refractive index higher than that of the organic resin. The microlens 32 may be formed of a coatable material obtained by dispersion of TiO₂, which is finely granulated, into the organic resin.

Thus, the refractive index n2 of the microlens 32 is about 2.0 and thus can sufficiently exhibit the light-collecting characteristics. The material of the microlens 32 is not limited to the TiO₂. For example, the material of the microlens 32 may be any one of P-SiN (plasma CVD silicon nitride), SiO₂ (silicon oxide) containing C (carbon) and/or N (nitrogen), ZrO₂ (zirconium oxide), and TaO (tantalum oxide). In addition, the material of the microlens may be a coatable material obtained by dispersion of these materials, which is finely granulated, into the organic resin. When the microlens 32 is formed of these materials, the refractive index n2 of the microlens 32 may be about 1.7 to 2.0.

In such a camera module 1, as illustrated in FIG. 2, the light incident from the image pickup lens 10 passes through the flattened layer 4 and forms the image on an incident-side surface of the microlens 32. Specifically, light incident on the flattened layer 4 at an incident angle α with respect to a normal line of the flattened layer 4 is refracted at a refractive angle β smaller than the incident angle α with respect to the normal line of the flattened layer 4 and is then incident on the microlens 32.

Here, as described above, the refractive index n1 of the flattened layer 4 is 1.3 to 1.5, and the refractive index n2 of the microlens 32 is 1.7 to 2.0. That is, the refractive index n2 of the microlens 32 is 1.3 times or more of the refractive index n1 of the flattened layer 4. In other words, the refractive index n1 of the flattened layer 4 is 1/1.3 times or less of the refractive index n2 of the microlens 32.

Thus, the microlens 32 can sufficiently exhibit the light-collecting characteristics and collect the incident light onto the photoelectric conversion element. The light incident to the photoelectric conversion element is converted into the signal charge by the photoelectric conversion element.

In addition, as illustrated in FIG. 2, a distance T of the flattened layer 4 between the light receiving surface of the microlens 32 and a light-incident-side surface of the flattened layer 4 needs to be larger than a focal depth d so as to ensure high resolving power ω of the image pickup lens 10.

The focal depth d represents a range where when the lens is focused on one point, a clear image can be formed at front and rear of that point. The focal depth d is proportional to the refractive index n1 of the flattened layer 4 and the wavelength λ of the light incident on the flattened layer 4 and is inversely proportional to the square of the numerical aperture NA of the image pickup lens 10, so that it can be expressed by the relational expression represented in Formula (4) to be described below.

d=n1·λ/(NA)² (4)

When the above distance T is smaller than the focal depth d, the light incident from the image pickup lens 10 forms the image on the surface of the flattened layer 4 without passing through the flattened layer 4, and thus the resolving power ω of the image pickup lens 10 is lowered.

Therefore, when the camera module 1 satisfies the condition represented in Formula (5) to be described below, the light incident from the image pickup lens 10 passes through the flattened layer 4 and forms the image on the incident-side surface of the microlens 32, so that it is possible to ensure high resolving power ω of the image pickup lens 10.

T>(n1·λ)/(NA)² (5)

In the camera module 1 according to the first embodiment, as described above, the flattened layer 4 is provided on the surface of the sensor substrate 2 to cover the plurality of microlenses 32 having the refractive index n2 of 1.7 to 2.0. The refractive index n1 of the flattened layer 4 is 1/1.3 times or less of the refractive index n2 of the microlens 32.

By such a configuration, in the camera module 1, the resolving power ω of the image pickup lens 10 can be increased while the light-collecting characteristics of the microlens 32 are maintained in a high state. As a result, the resolution of the camera module 1 is improved.

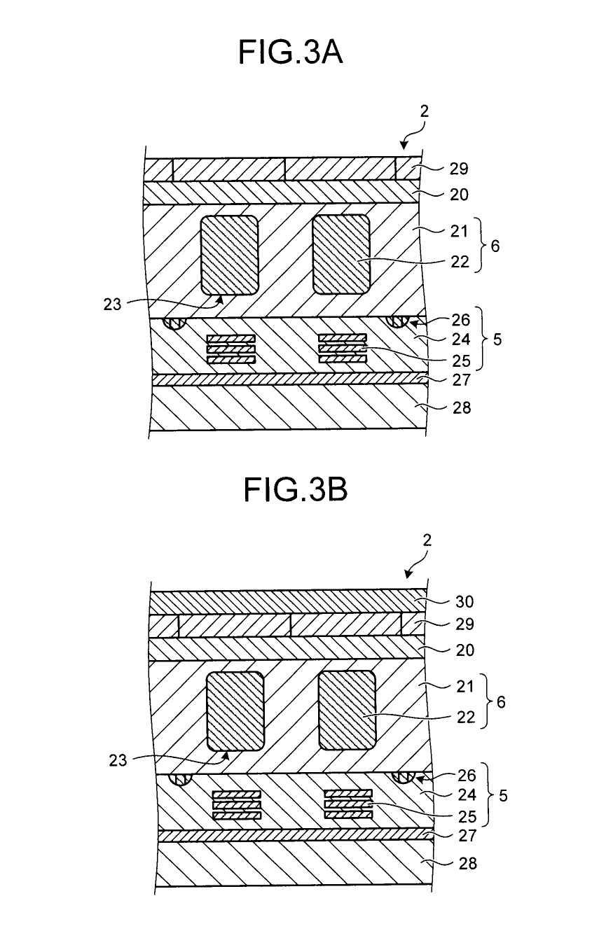

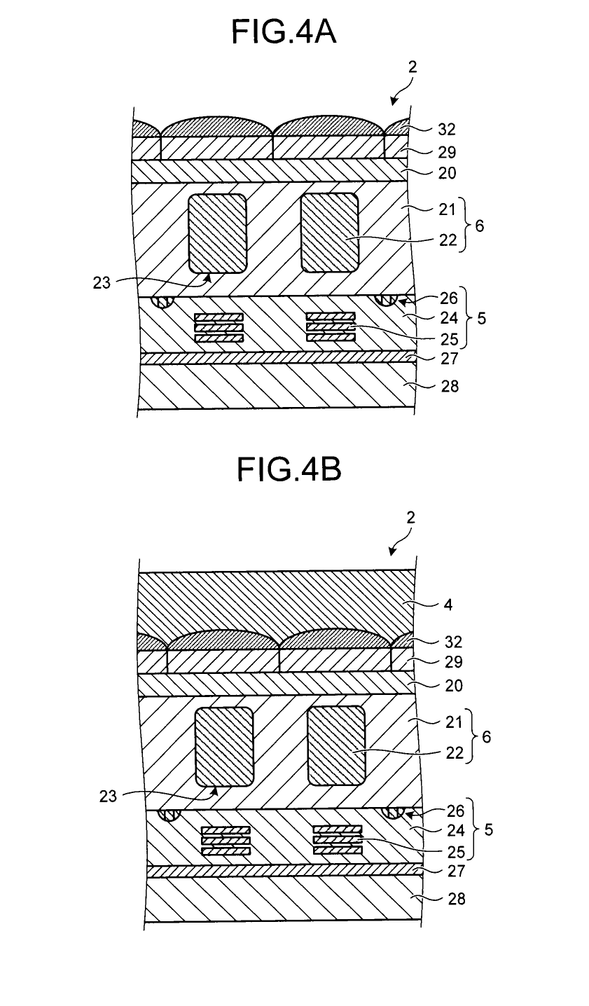

A method of fabricating the solid-state image pickup device 14 according to the first embodiment will be described below with reference to FIGS. 3A and 3B and FIGS. 4A and 4B. Here, the sensor substrate 2 has the same configuration as a general sensor substrate having a CMOS sensor. Therefore, a process of fabricating the microlens 32 and the flattened layer 4 on the light receiving surface of the sensor substrate 2 will be described herein. FIGS. 3A and 3B and FIGS. 4A and 4B are schematic cross-sectional views illustrating the process of fabricating the solid-state image pickup device 14 according to the first embodiment, respectively.

As illustrated in FIG. 3A, the sensor substrate 2 has a structure in which a wiring layer 5, a semiconductor layer 6, a waveguide layer 20, and a color filter 29 are stacked in this order on the surface of a support substrate 28 through an adhesive layer 27. The wiring layer 5 is configured such that a wiring 25, a readout electrode 26 and the like are buried in an insulation film 24.

The semiconductor layer 6 is configured such that an N-type Si region 22 is arranged in an array shape in a P-type Si layer 21. In addition, the semiconductor layer 6 includes a photoelectric conversion element 23 as a photodiode which is formed by PN junction between the P-type Si layer 21 and the N-type Si region 22.

The waveguide layer 20 is formed by a transparent film to guide the light transmitted through the microlens 32 to the photoelectric conversion element 23. The color filter 29 is formed at a position corresponding to the light receiving surface of the photoelectric conversion element 23 to selectively transmit any of color light of red, green, blue, or white. The wiring layer 5, the semiconductor layer 6, the waveguide layer 20, and the color filter 29 are formed using, for example, a fabrication process of the general CMOS sensor.

After the color filter 29 is formed, as illustrated in FIG. 3B, a high refractive index material film 30 made of a material obtained by dispersing fine particles of, for example, TiO₂ into an organic resin is formed on the surface of the color filter 29. For example, the high refractive index material film 30 is formed by a spin coating method.

Subsequently, a resist (not illustrated) is applied onto the surface of the high refractive index material film 30 to form a resist film, and the resist film is formed to have a predetermined pattern by exposure and development using a photomask.

Thereafter, the resist pattern is melted by heat treatment and thus the light receiving surface of the resist pattern is formed in a semispherical shape. Then, the pattern of the resist film is transferred onto the high refractive index material film 30 by dry etching, thereby forming the semispherical microlens 32 as illustrated in FIG. 4A.

The method of forming the microlens 32 is not limited to the method described above, but, for example, the semispherical microlens 32 may be formed from the high refractive index material film 30 by an etching method using a grating mask.

Thereafter, as illustrated in FIG. 4B, the flattened layer 4 is formed on the light-incident-side surface of the plurality of microlenses 32 so as to cover the plurality of microlenses 32, the flattened layer 4 being formed by dispersing fine particles of, for example, porous silica or hollow silica into an organic resin having a low refractive index. For example, the flattened layer 4 is formed by a spin coating method.

In the solid-state image pickup device 14 fabricated by the above method, the flattened layer 4 is formed on the surface of the sensor substrate 2 to cover the plurality of microlenses 32 having the refractive index n2 of 1.7 to 2.0. The refractive index n1 of the flattened layer 4 is 1/1.3 times or less of the refractive index n2 of the microlens 32.

For this reason, in the solid-state image pickup device 14, the resolving power ω of the image pickup lens 10 can be increased while the light-collecting characteristics of the microlens 32 are maintained in a high state. As a result, the resolution of the solid-state image pickup device 14 is improved.

### Second Embodiment

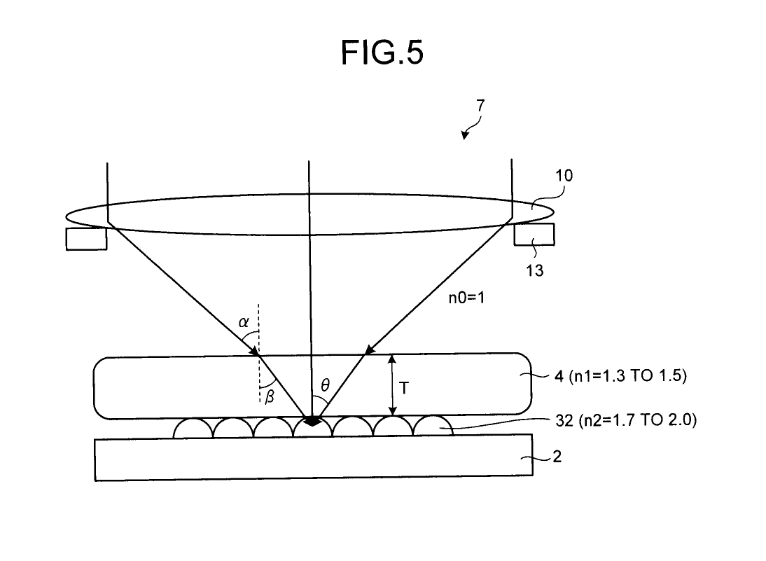

A camera module 7 according to a second embodiment will be described with reference to FIG. 5. The camera module 7 according to the second embodiment has the same configuration as the camera module 1 according to the first embodiment except that a sheet-like flattened layer 4 made of a resin dispersed with SiO₂ such as porous silica or hollow silica is placed on a light receiving surface of a microlens 32.

FIG. 5 is an explanatory diagram schematically illustrating the camera module 7 according to the second embodiment. As illustrated in FIG. 5, the flattened layer 4 is placed as one sheet on the light receiving surface of the microlens 32.

Even in the camera module 7 according to this embodiment, the refractive index n1 of the flattened layer 4 is 1.3 to 1.5, and the refractive index n2 of the microlens 32 is 1.7 to 2.0. That is, the refractive index n2 of the microlens 32 is 1.3 times or more of the refractive index n1 of the flattened layer 4. In other words, the refractive index n1 of the flattened layer 4 is 1/1.3 times or less of the refractive index n2 of the microlens 32.

For this reason, in the camera module 7, the resolving power ω of an image pickup lens 10 can be increased while the light-collecting characteristics of the microlens 32 are maintained in a high state. As a result, the resolution of the camera module 7 is improved.

Furthermore, in such a camera module 7, the flattened layer 4 made of one sheet is only placed on the light receiving surface of the microlens 32 and thus the resolution of the camera module 7 can be easily improved. Therefore, it is possible to easily cope with design changes of the camera module.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solid-state image pickup device comprising:
a sensor substrate on which a plurality of photoelectric conversion elements are arranged in a two-dimensional array shape;
microlenses that are respectively provided at positions facing light receiving surfaces of the plurality of photoelectric conversion elements, and collect incident light onto the photoelectric conversion elements; and
a flattened layer that is provided on a light incident side of the microlenses and has a refractive index which is higher than a refractive index of air and is 1/1.3 times or less of a refractive index of the microlenses.

2. The solid-state image pickup device according to claim 1, wherein the flattened layer covers the microlenses and is provided on the sensor substrate.

3. The solid-state image pickup device according to claim 1, wherein the microlenses have a refractive index of 1.7 to 2.0.

4. The solid-state image pickup device according to claim 1, wherein the microlenses contains any material of titanium oxide, silicon nitride, silicon oxide containing carbon and/or nitrogen, zirconium oxide, and tantalum oxide.

5. The solid-state image pickup device according to claim 1, wherein the flattened layer contains bubbles dispersed therein.

6. The solid-state image pickup device according to claim 1, wherein the flattened layer is a flat sheet that is provided on light receiving surfaces of the microlenses.

7. The solid-state image pickup device according to claim 4, wherein the microlenses is formed of an organic resin dispersed with the any material of the titanium oxide, the silicon nitride, the silicon oxide containing carbon and/or nitrogen, the zirconium oxide, and the tantalum oxide.

8. A camera module comprising:
a sensor substrate on which a plurality of photoelectric conversion elements are arranged in a two-dimensional array shape;
microlenses that are respectively provided at positions facing light receiving surfaces of the plurality of photoelectric conversion elements, and collect incident light onto the photoelectric conversion elements;
an image pickup lens that collects light from an object onto the microlenses; and
a flattened layer that is provided between the image pickup lens and the microlenses and has a refractive index which is higher than a refractive index of air and is 1/1.3 times or less of a refractive index of the microlenses.

9. The camera module according to claim 8, wherein the flattened layer covers the microlenses and is provided on the sensor substrate.

10. The camera module according to claim 8, wherein the microlenses have a refractive index of 1.7 to 2.0.

11. The camera module according to claim 8, wherein the microlenses contains any material of titanium oxide, silicon nitride, silicon oxide containing carbon and/or nitrogen, zirconium oxide, and tantalum oxide.

12. The camera module according to claim 8, wherein the flattened layer contains bubbles dispersed therein.

13. The camera module according to claim 8, wherein the flattened layer is a flat sheet that is provided on light receiving surfaces of the microlenses.

14. The camera module according to claim 11, wherein the microlenses are formed of an organic resin dispersed with the any material of the titanium oxide, the silicon nitride, the silicon oxide containing carbon and/or nitrogen, the zirconium oxide, and the tantalum oxide.

15. The camera module according to claim 8, wherein a distance between the light receiving surface of the microlenses and the light receiving surface of the flattened layer is larger than a focal depth of the image pickup lens.
